(19) United States
(12) Patent Application Publication
(10) Pub. No.: US 2026/0156419 A1
(43) Pub. Date: Jun. 4, 2026

(54) APPARATUS AND METHOD FOR USING A LOW REFERENCE VOLTAGE WITH A MEMS DEVICE

(71) Applicant: Knowles Electronics, LLC, Itasca, IL (US)

(72) Inventor: Michael Jennings, McKinney, TX (US)

(21) Appl. No.: 18/964,843

(22) Filed: Dec. 2, 2024

(51) Int. Cl. H04R 19/04; H10D 80/20

(52) U.S. Cl. CPC H04R 19/04; H10D 80/251; H04R 2201/003

(57) ABSTRACT

A sensor component can include a housing, an electrical interface, and a capacitive transducer, the capacitive transducer including a first electrode and a second electrode. The sensor component can include an electrical circuit including a bias voltage source coupled to the first electrode. The bias voltage source can include a voltage booster circuit coupled to the charge pump and coupled to a reference voltage source. The voltage booster circuit can receive a reference voltage and a clock signal, increase the reference voltage, and increase a voltage of the clock signal provided to a charge pump clock input based on the increased reference voltage. The voltage booster circuit can provide the increased reference voltage to the charge pump input. The voltage booster circuit can also include a switch control circuit that controls at least two transistors of the voltage booster circuit independent of the reference voltage.

### BACKGROUND

### Field

The present disclosure is directed to a microelectromechanical systems (MEMS) device. More particularly, the present disclosure is directed to an apparatus and method for using a low reference voltage with a MEMS device.

### Background

Presently, consumer electronic devices like mobile phones, personal computers, smart speakers, hearing aids, and True Wireless Stereo (TWS) earphones among other host devices commonly incorporate one or more small sensors, such as microphones, actuators, and/or other sensors. Advancements in micro and nanofabrication technologies have led to the development of MEMS device sensors having progressively smaller size and different form-factors.

Due to small size requirements of sensor packages, MEMS devices are often employed with small power supplies that output low voltages. However, a capacitive element of MEMS device transducers requires higher voltages than those provided by small power supplies. Thus, a charge pump is used to bias the capacitive element at a voltage much higher than the voltage provided by the power supply. The range of bias voltages are often between 10V and 40V depending on the MEMS transducer and may need to have a wider range depending on the transducer. This bias voltage is typically developed by using a reference voltage and a series of cross-coupled inverter pump stages where a multiplication factor of the reference voltage is proportional to the number of pump stages. Due to the small size requirements of the sensor packages, there is a need to reduce the number of charge pump stages while still providing the required voltage for a given MEMS transducer.

The approaches described in this section are approaches that could be pursued, but not necessarily approaches that have been previously conceived or pursued. Therefore, unless otherwise indicated, it should not be assumed that any of the approaches described in this section qualify as background merely by virtue of their inclusion in this section. Furthermore, it should not be assumed that any of the approaches described in this section are well-understood, routine, or conventional merely by virtue of their inclusion in this section.

### BRIEF DESCRIPTION OF THE DRAWINGS

In order to describe the manner in which advantages and features of the disclosure can be obtained, a description of the disclosure is rendered by reference to specific embodiments thereof which are illustrated in the appended drawings. These drawings depict only example embodiments of the disclosure and are not therefore to be considered to be limiting of its scope. The drawings may have been simplified for clarity and are not necessarily drawn to scale.

FIG. 1A is an exploded view of a representative sensor according to an example embodiment.

FIG. 1B is a side cross-section view of the representative sensor according to an example embodiment.

FIG. 2 is a schematic diagram of a transducer circuit according to an example embodiment.

FIG. 3 is a schematic diagram of a charge pump stage according to an example embodiment.

FIG. 4 is an illustration of two charge pump stages of a charge pump according to an example embodiment.

FIG. 5 is an example block diagram of a bias voltage source according to an example embodiment.

FIG. 6 is an illustration of a voltage booster stage according to an example embodiment.

FIG. 7 is an illustration of a first switch control circuit according to an example embodiment.

FIG. 8 is an illustration of a second switch control circuit according to an example embodiment.

FIG. 9 is an example diagram of signals applied to the voltage booster stage according to an example embodiment.

FIG. 10 is an example illustration of a bootstrapping circuit according to an example embodiment.

FIG. 11 is an example illustration of a bias voltage source according to an example embodiment.

FIG. 12 is an example illustration of a bias voltage source according to an example embodiment.

### DETAILED DESCRIPTION

In the following description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present invention. The drawings illustrate aspects of disclosed embodiments while omitting elements that are known to those skilled in the art for practicing the disclosed embodiments.

At least some embodiments can provide an apparatus and method for using a low reference voltage with a MEMS device. In an example embodiment, a sensor component includes a housing, and an electrical interface disposed on an exterior of the housing. The sensor component includes a capacitive transducer disposed in the housing, the capacitive transducer including a first electrode and a second electrode. The sensor component includes an electrical circuit disposed in the housing and electrically coupled to the transducer and the electrical interface, where the electrical circuit includes a bias voltage source coupled to the first electrode.

The bias voltage source includes a charge pump including a clock input. In an embodiment, the charge pump can include a plurality of charge pump stages, where each charge pump stage includes a charge pump stage clock input. Each charge pump stage clock input can include two clock inputs, where one clock input receives a clock signal out of phase from a clock signal received at the other clock input. The bias voltage source also includes a reference voltage source that provides a reference voltage. The bias voltage source further includes a clock circuit that outputs a clock signal with a clock voltage.

The bias voltage source includes a voltage booster circuit coupled to the charge pump and coupled to the reference voltage source. The voltage booster circuit receives the reference voltage and the clock signal, increases the reference voltage, and increases a voltage of the clock signal provided to the charge pump clock input based on the increased reference voltage. The charge pump can include a charge pump input, and the voltage booster circuit provides the increased reference voltage to the charge pump input.

In an embodiment, the voltage booster circuit includes a plurality of voltage booster stages, where a first voltage booster stage increases a clock voltage provided to a second voltage booster stage. The first voltage booster stage can also increase the reference voltage and provide the increased reference voltage to the second voltage booster stage.

In an embodiment, the voltage booster circuit includes a voltage level shifter coupled to an output of the first voltage booster stage and coupled to a clock input of the second voltage booster stage. The voltage level shifter increases the clock voltage provided to the second voltage booster stage based on an increased reference voltage output from the first voltage booster stage.

In an embodiment, the electrical circuit includes a multiplexer that selectively enables a voltage booster output signal provided from at least one voltage booster stage of the plurality of voltage booster stages to the charge pump. The voltage booster output signal can be a multiplied reference voltage signal and/or an increased voltage clock signal.

In an example embodiment, the voltage booster circuit includes at least two transistors, each including a gate and a source. Each of the at least two transistors can be part of a respective inverter. The voltage booster circuit includes a switch control circuit coupled between the gates of the at least two transistors, where the switch control circuit controls the at least two transistors independent of the reference voltage. The switch control circuit is considered a switch control circuit because the transistors act as switches and the switch control circuit controls the switching function of the transistors. In particular, the switch control circuit makes the gate to source voltage of the transistors independent of the reference voltage. For example, the switch control circuit sets Vgs based on voltage based on a source voltage different from the reference voltage. The switch control circuit turns the transistors on and off based on a gate voltage Vg that makes the gate control independent of a reference voltage applied at the source.

In an embodiment, the at least two transistors include a first PMOS transistor having a gate, a first NMOS transistor having a gate, a second PMOS transistor having a gate, and a second NMOS transistor having a gate. The switch control circuit can control a voltage applied to a gate of a PMOS transistor separately from a voltage applied to a gate of an NMOS transistor. In an embodiment, the switch control circuit includes a first switch circuit coupled between the first PMOS transistor gate and the second PMOS transistor gate and includes a second switch circuit coupled between the first NMOS transistor gate and the second NMOS transistor gate.

In an embodiment, the first switch circuit includes an inverted clock booster that provides an inverted boosted clock voltage source signal to the first PMOS transistor gate and the second PMOS transistor gate. The second switch circuit comprises a clock booster that provides a boosted clocked voltage source signal to the first NMOS transistor gate and the second NMOS transistor gate. In an example embodiment, the voltage booster circuit includes a first voltage booster capacitor and a second voltage booster capacitor driven by respective complimentary clock drivers. The complimentary clock drivers control charging and discharging of each respective capacitor.

In an example embodiment, the charge pump includes a charge pump output. The bias voltage source includes a low pass filter coupled between the charge pump output and the capacitive transducer. In an example embodiment, the electrical circuit can include a non-inverting amplifier including an input coupled to the capacitive transducer, where the non-inverting amplifier has an input impedance greater than 1 TΩ. The input impedance minimum can be set by how much capacitance the MEMS device, such as a MEMS, motor has. Some microphones may have GΩ input impedance if the MEMS capacitance is large and is determined by desired acoustic lower bandwidth.

As described above, a charge pump is used to bias the MEMS capacitive element at a voltage much higher than the power supply. The range of bias voltages is often between 10V and 40V depending on the motor design and other motor designs and applications may require other values, a wider range, or a narrower range. This bias voltage can be developed by using a reference voltage and a series of cross-coupled inverter pump stages where a multiplication factor of the reference voltage is proportional to the number of pumping stages. Also, due to the small size requirements of the sensor packages, it is useful to reduce the number of charge pump stages while still providing the required voltage for a given MEMS transducer.

For 0.9V battery applications, the charge pump multiplication factor is usually very high, and a series of multiplier stages can be utilized such that the reference is pre-multiplied before driving a multi-stage charge pump. Thus, instead of a reference voltage of 0.75V, the reference can be pre-multiplied, such as by 2 with a doubler, to drive the remaining charge pump core stages with 1.5V which reduces the total number of pumping stages.

Different MEMS motors require different bias voltages. The wide final bias voltage range needed for the different MEMS motors, coupled with a high multiplication pumping factor, results in both high and low reference voltages depending on which MEMS motor is used. In other words, to make a 44V charge pump output with a charge pump multiplication factor of 59, the needed reference voltage can be 0.75V, while for a 20V output the needed reference can be ˜0.34V. Such a low reference voltage is difficult to use with a standard charge pump where the cross coupled inverter switches are driven with the reference voltage. This is especially true at startup using series doublers to pre-multiply the reference voltage to use with the charge pump core stages because more load current demand at startup requires lower on-resistance for the switches.

In some embodiments, the low on-resistance switch requirement at startup can be satisfied when using very low reference voltages by decoupling the transistors/switches from the reference voltage and driving the switches with appropriate bootstrapped signals using a higher voltage, such as a VDD source voltage. In this way, a more robust pumping doubler can be developed to pre-multiply the reference voltage such that low switch on-resistance is maintained for initial stages. A low initial reference voltage can be of diminishing concern in downstream stages because the reference is boosted for later stages.

At least some embodiments can decouple the reference voltage from controlling the switches in the charge pump core by using switch control circuits, such as separate bootstrapped switch control circuits, with higher voltages, such as VDD. This decoupling of the switch control from the reference voltage increases the gate-to-source voltage Vgs of the switches, which leads to lower on-resistance of the switches, all while not changing the reference multiplication factor of the overall charge pump transfer function assuming parasitic losses are discounted. The switch control voltage can also be boosted/doubled to further lower switch on-resistance. Additionally, separate control of PMOS switches from NMOS switches in the booster/doubler allows for enhanced break before make control such that shoot through current from output of booster/doubler stage to input of booster/doubler stage can be minimized for increased charge pump efficiency.

At least some embodiments can provide for different output voltages of the charge pump for different applications. For example, some sensor circuits may require different voltages than others and the output voltage of the charge pump can be adjusted, such as programmed or trimmed, for different applications without issues caused by low reference voltages. As an example, the range of the charge pump can be ˜20V to 40V with a Vref of ˜400mV to 750 mV. Different ranges can also be used for different applications. Embodiments can provide for wide ranges of useful charge pump voltages by allowing lower reference voltages. For example, a multiplexer can be used to set different charge pump voltages, to provide trimmable reference voltages, to short out charge pump stages, and for other purposes.

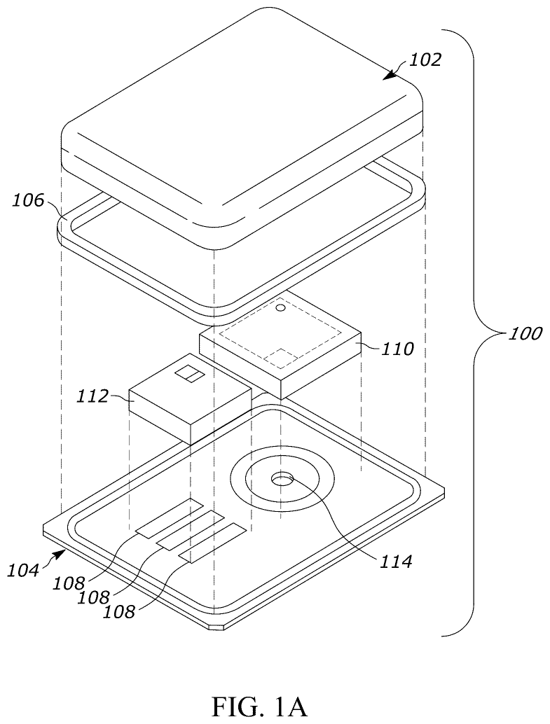

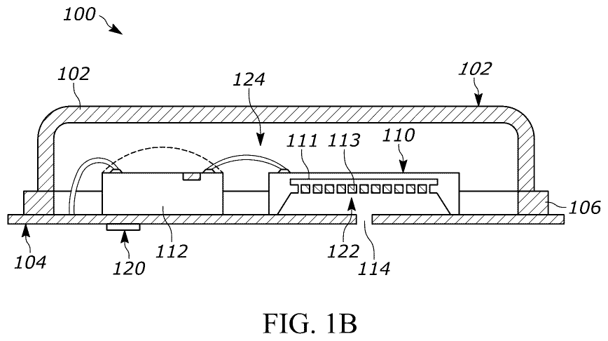

FIG. 1A is an exploded view of a representative sensor component 100 according to an example embodiment. FIG. 1B is a side cross-section view of the representative sensor component 100 according to an example embodiment. A sensor component generally comprises a capacitive transducer and an electrical circuit disposed in a housing having an external electrical interface. In a general example embodiment, a sensor component includes a housing, and an electrical interface disposed on an exterior of the housing. The sensor component includes a capacitive transducer disposed in the housing, the capacitive transducer including a first electrode and a second electrode. The sensor component includes an electrical circuit disposed in the housing and electrically coupled to the transducer and the electrical interface, where the electrical circuit includes a bias voltage source coupled to the first electrode.

For example, a representative sensor component 100 comprises a housing having a cover 102 mounted on a base 104. A guard ring 106 is optionally located between the cover and the base 104, such as a substrate. The cover 102, guard ring 106, and base 104 can comprise conductive materials to electrically shield parts of the sensor within the housing. The cover 102 can be a metal can or metallized PCB materials. The base 104 can also be a PCB comprising one or more layers.

Generally, a transducer 110 is electrically coupled to an electrical circuit 112 and the electrical circuit is electrically coupled to the external electrical interface of the housing. The transducer generally comprises at least one movable electrode (e.g., a membrane or diaphragm) and a fixed electrode. Deflection of the movable electrode relative to the fixed electrode in response to a sensed condition provides a basis for generating an electrical signal representing the sensed condition. Representative transducers include capacitive microelectromechanical systems (MEMS) device, also referred to as a MEMS die or MEMS motor. Other suitable transducers include electret, piezo and photocell devices, among others having fixed and movable electrodes. The electrical circuit can be implemented as one or more an integrated circuits (IC) or ASICs.

In a possible embodiment, the representative sensor component 100 is implemented as a microphone comprising transducer 110, such as an acoustic transducer like a MEMS transducer, disposed over an sound port 114 in the base 104. The transducer 110 separates the housing into a front volume 122 acoustically coupled to the sound port 114 and a back volume 124 on the opposite side of the transducer 110 from the sound port 114.

In an example embodiment, the transducer 110 comprises the first electrode in the form of a diaphragm 111 and the second electrode in the form of a perforated backplate 113. The diaphragm 111 is movable relative to the perforated backplate 113 in response to changes in acoustic pressure entering an interior of the housing via the sound port 114. Instead of being disposed over an acoustic port on the base 104, the transducer 110 can be disposed over an acoustic port in the cover. In still other implementations, the sensor is a vibration sensor or accelerometer devoid of an acoustic port in the housing. The transducer of a vibration sensor or accelerometer can be implemented as a proof mass.

The electrical circuit, such as an IC, 112 is disposed in the housing and electrically connected to contacts 108 on the base 104. The MEMS transducer 110 is wire bonded to the electrical circuit 112 and the electrical circuit 112 is wire bonded to the contacts 108 on the base 104. Alternatively, the electrical circuit 112 can be surface mounted on the contacts 108. The contacts 108 on the base 104 can be electrically connected to an electrical interface 120 on the exterior of the housing by vias extending through base 104. Alternatively, the electrical circuit 112 can be mounted on some other surface of the housing interior, like the cover 102, and connected to an electrical interface vias conductors extending through the side walls or other structure of the housing.

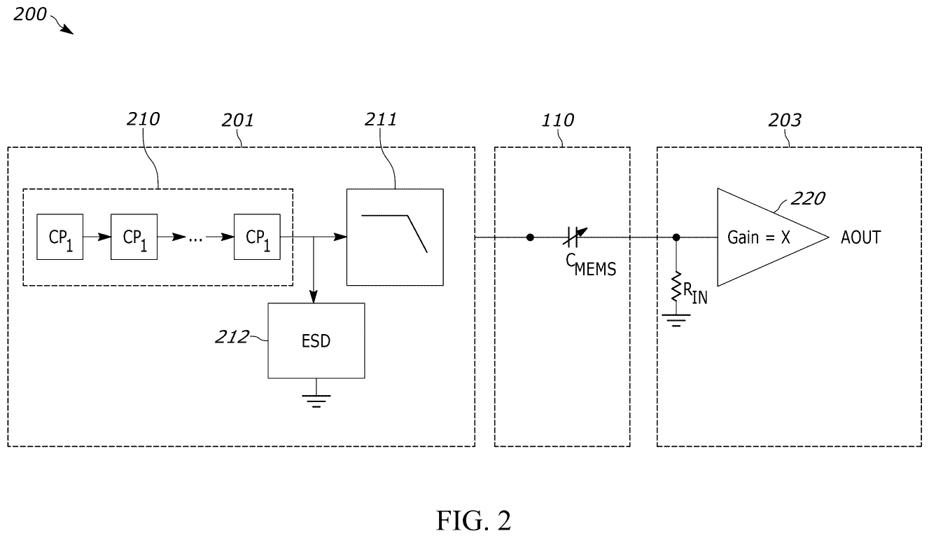

FIG. 2 is a schematic diagram of a transducer circuit 200 according to an example embodiment. The transducer circuit 200 generally includes features of the electrical circuit 112, which can include such as a bias voltage source 201 coupled to an electrode of a capacitive transducer 110. The bias voltage source 201 includes a charge pump 210. The bias voltage source 201 includes a low pass filter 211 coupled between an output of the charge pump and the capacitive transducer 110. The transducer circuit 200 can also include a non-inverting amplifier 220 having an input coupled to the capacitive transducer 110, where the non-inverting amplifier 220 has an input impedance greater than 1 TΩ, where the impedance is related to motor capacitance and signal path bandwidth.

To elaborate, electrical components of the transducer circuit 200 can be part of the electrical circuit 112. The transducer circuit 200 generally includes the bias voltage source 201, the transducer 102, and an amplification circuit 203. The bias voltage source 201 can be a DC bias circuit. In some embodiments, the bias voltage source 201 and the amplification circuit 203 are integrated into the electrical circuit 112. In some embodiments, the amplification circuit 203 may be part of a host device. In some embodiments, the amplification circuit 203 may be a signal conditioning circuit that includes a buffer, high pass filter, and/or an analog to digital converter (e.g., in digital microphones). The amplification circuit 203 can be a non-inverting amplifier including an input coupled to the capacitive transducer 110, where the non-inverting amplifier has an input impedance greater than 1 TΩ

The bias voltage source 201 is arranged to provide a DC bias signal to the transducer 110. In some embodiments, the bias voltage source 201 includes a charge pump, such as a multi-stage charge pump circuit 210, and a low pass filter (LPF) circuit 211. In some embodiments, the bias voltage source 201 further includes an electrostatic discharge (ESD) circuit 212 coupled to an output of the bias voltage source 201, coupled to ground or other useful voltage, and configured to discharge electrostatic charges.

In some embodiments, bias voltage source 201 may include other types of DC amplifying circuits as an alternative or in addition to the multi-stage charge pump circuit 210. The multi-stage charge pump 210 is configured to convert an input DC voltage to an output DC voltage that is higher in magnitude than the input DC voltage. For example, the multi-stage charge pump circuit 210 may have an input from a battery or other power source that is around 5 volts and the output of the multi-stage charge pump circuit 210 may have an output that is 50 volts or higher. In some embodiments, the increase in DC voltage from the input to the output of the multi-stage charge pump circuit 210 is based on the number of charge pump stages CP_{1-N} or other DC amplifying circuits within the multi-stage charge pump circuit 210. The LPF 211 is arranged to receive a signal from the output of the multi-stage charge pump circuit 210 and output the DC bias signal to a first terminal of the transducer 110. In some embodiments, where the mechanical compliance of the transducer 102 is small, the output voltage of the bias voltage source 201 may be increased in order for the sensor component to have increased sensitivity and SNR.

The transducer 102 is arranged to receive the DC bias signal from the bias voltage source 201 and to generate an electrical signal that is indicative of sensed acoustic energy. The electrical signal is generated with the DC bias signal as a reference voltage. For example, the DC bias signal may be 55 volts (V), and the electrical signal generated by the transducer 102 may be a signal within the range of a few millivolts (mV) to a few hundred millivolts (e.g., 0.001 mV-100 mV.) The electrical signal is then provided to the amplification circuit 203. As one example, the electrical signal may be amplified by the amplification circuit 203 and further processed by an analog to digital converter such as to create a digital representation of the electrical signal and the acoustic activity that the electrical signal represents.

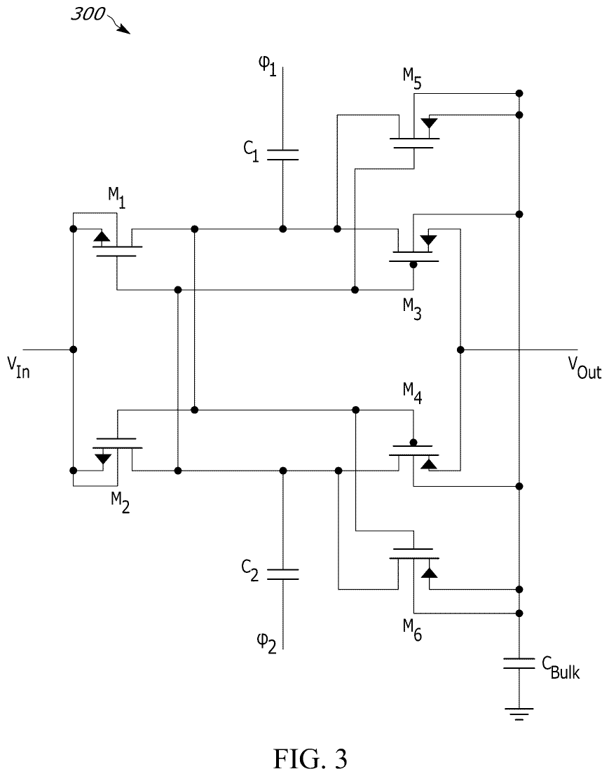

FIG. 3 is a schematic diagram of a charge pump stage 300 according to an example embodiment. In some embodiments, the charge pump stage 300 may be implemented as one of the multiple charge pump stages CP_{1-N} of the bias voltage source 201 of FIG. 2. It is to be appreciated that in other embodiments, other types, forms, or configurations of charge pump stages may be implemented. For example, in some embodiments, a charge pump stage may be implemented with one or more capacitors and one or more semiconductor devices. In some embodiments, the one or more semiconductor devices may include one or more diodes and/or one or more transistors.

The charge pump stage 300 includes an input Vᵢₙ, multiple transistors M₁₋₆, a first capacitor C₁, a second capacitor C₁, and an output Vₒᵤₜ. In a particular implementation, the M₅ and M₆ transistors can be removed. The charge pump stage 300 is configured to connect to a clock circuit via a first terminal φ₁ and a second terminal φ₂. The clock circuit is used to drive the charge pump stage 300. In some embodiments, the clock circuit generates a two phase, non-overlapping signal with one phase configured to be supplied to the first terminal φ₁ and a second phase configured to be supplied to the second terminal φ₂. In other embodiments, more than two phases may be implemented. The charge pump stage 300 receives an input DC voltage at the input Vᵢₙ and outputs a DC voltage that is higher in magnitude than the input DC voltage at the output Vₒᵤₜ. In some implementations, the output Vₒᵤₜ of the charge pump stage 300 may be connected to an input of a second charge pump stage 300 such that the charge pump stages are cascaded and an output DC voltage of the multiple charge pump stages may reach higher voltages.

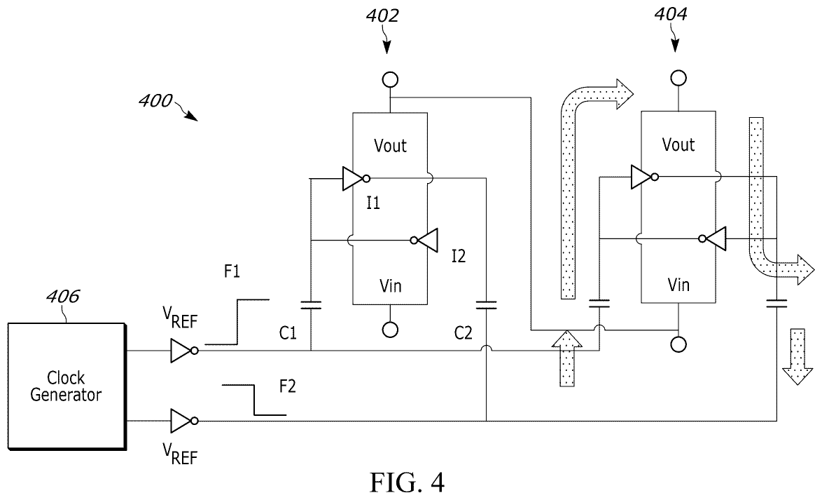

FIG. 4 is an illustration of two charge pump stages 402 and 404 of a charge pump 400 according to an example embodiment. Each stage is sometimes called a voltage doubler by those skilled in the art, where each stage is made with cross coupled inverters I1 and I2 driven by capacitors C1 and C2 with an overlapping clock generator 406. A high F1 in this simplified drawing discharges charged cap C1 while a low F2 charges discharged cap C2. Also, when F1 does go high (0->Vref), I1 connects Vin to the top plate of C2, which charges C2 from the output of the previous stage (Vin) when there are earlier stages. Conversely, when F2 goes low (Vref->0), I2 connects Vout to C1 which transfers charge from C1 to the next stage 404. The final voltage output from a charge pump is approximately the number of stages multiplied by Vref when the voltage Vin provided to the first stage 402 is Vref and the clock voltage is Vref.

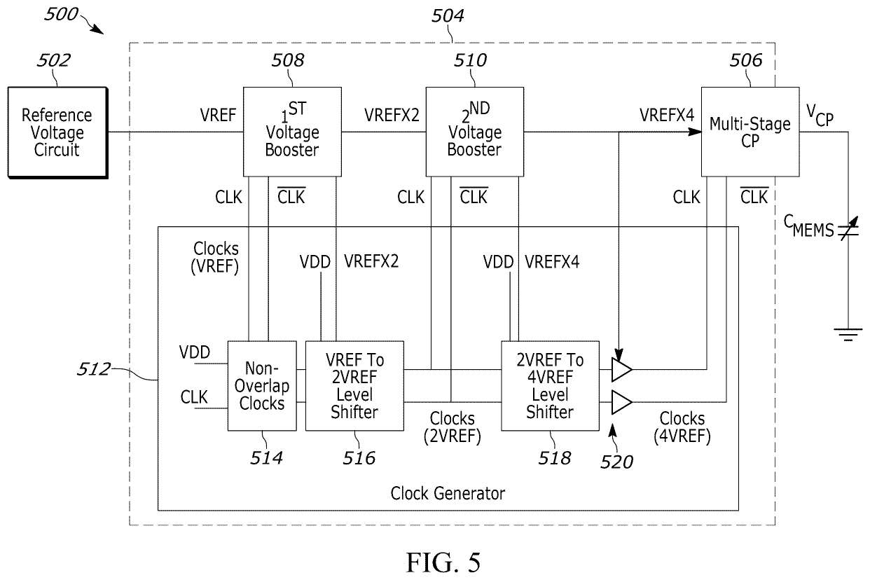

FIG. 5 is an example block diagram of a bias voltage source 500 according to an example embodiment. Generally, the bias voltage source 500 includes a charge pump having a clock input. In an embodiment, the charge pump can include a plurality of charge pump stages, where each charge pump stage includes a charge pump stage clock input. Each charge pump stage clock input can include two clock inputs, where one input receives a clock signal out of phase from a clock signal received at the other input. The bias voltage source 500 includes a reference voltage source that provides a reference voltage.

The bias voltage source 500 also includes a clock circuit that outputs a clock signal with a clock voltage. The bias voltage source 500 further includes a voltage booster circuit coupled to the charge pump and coupled to the reference voltage source. The voltage booster circuit receives the reference voltage and the clock signal, increases the reference voltage, and increases a voltage of the clock signal provided to the charge pump clock input based on the increased reference voltage. The charge pump can include a charge pump input, and the voltage booster circuit provides the increased reference voltage to the charge pump input.

The voltage booster circuit can include a plurality of voltage booster stages, where a first voltage booster stage increases a clock voltage provided to a second voltage booster stage. The first voltage booster stage can also increase the reference voltage and provide the increased reference voltage to the second voltage booster stage.

In an embodiment, the voltage booster circuit comprises a voltage level shifter coupled to an output of the first voltage booster stage and coupled to a clock input of the second voltage booster stage. The voltage level shifter increases the clock voltage provided to the second voltage booster stage based on an increased reference voltage output from the first voltage booster stage.

For example, the bias voltage source 500 includes a reference voltage circuit 502, a voltage booster circuit 504, and a multi-stage charge pump 506. The bias voltage source 500 is coupled to a capacitive MEMS transducer C_{MEMS}. The voltage booster circuit 504 includes at least one voltage booster stage 508 and 510 and a clock generator 512. The clock generator includes a non-overlapping clock circuit 514 and at least one voltage level shifter 516 and 518. An overlapping clock circuit may be used instead of a non-overlapping clock circuit. The voltage level shifters 516 and 518 can be charge pumps or other level shifters. Each voltage level shifter may be considered part of respective voltage booster stages, and additional voltage booster stages and level shifters may also be present.

In operation, the non-overlapping clock circuit 514 generates dual phase non-overlapping clocks either having a period of time where the clocks are both high before one transitions low, or both low before one transitions high. It creates clocks that drive switched capacitors of the first voltage booster stage 508. The first voltage booster stage 508 receives a reference voltage Vref from the reference voltage circuit 502 and creates the 2× Vref (doubled Vref) supply for the next voltage booster stage 510 or for the input of the charge pump 506 if the second voltage booster stage 510 is not present. It also creates the 2× Vref voltage for the first voltage level shifter 516.

The level shifter 516 is a clock driver that takes Vref and level shifts the clocks to 2× Vref such that the driver supply is running off the 2× Vref supply generated by 1st booster stage. If additional boosters are present, the level shifter 516 will also drive the inputs to the following level shifter 518 as well as driving the switched capacitors of the next voltage booster stage 510. If no additional boosters are present, the level shifter 516 will drive, such as via drivers 520, sequential core cells of the charge pump 506.

The voltage booster stages 508 and 510 can be voltage boosters, voltage multipliers, voltage doublers, and may include switch control circuits, such as bootstrapped pump capacitor transistors, described in later embodiments. Each voltage booster increases a voltage provided at an input to the booster. For example, the first voltage booster stage 508 creates a 2× Vref output voltage from a Vref input voltage when its pump capacitors (not shown) are also driven with Vref referenced clock signals from the clock circuit 514.

The multi-stage charge pump 506 includes multiple charge pump core stages, such as a number N of charge pump doubler stages, where pump capacitors of each stage are driven from drivers powered from the final reference voltage. For example, drivers 520 can use the Vref×4 (quadrupled Vref) voltage from the second voltage booster stage 510 to drive the clock signal up to 4× Vref and provide the increased clock signal to charge pump stages of the charge pump 506. The final reference voltage Vref×4 can also be used as the input to the charge pump 506. The charge pump 506 increases the final reference voltage Vref×4 based on the increased clock signal and the number of stages.

For example, an initial clock (0 to VDD) creates non-overlap inputs for both the Vref to 2Vref level shifter 516 and the first voltage booster stage 508. The first voltage booster stage 508 creates the supply Vref×2 for the 2Vref to 4Vref first level shifter 516. The output of the first voltage booster stage 508 is buffered to create non-overlap clocks for second voltage booster stage 510, which provides the supply Vref×4 for the 2Vref to 4Vref second level shifter 518. It is again noted that overlapping clock signals may also be used for the clocks in the disclosed embodiments. The output of the second level shifter 518 is buffered and drives the multi-stage charge pump 506 via the drivers 520.

Each stage of the voltage booster circuit 504 and charge pump 506 adds the clocking voltage to the reference voltage. In the present embodiment, the voltage booster circuit 504 quadruples the reference voltage input to the charge pump 506, and also quadruples the clock signals as well. This effectively multiplies the charge pump stages by four, as if there are four times as many stages. While useful in many applications, it is noted the voltage booster circuit 504 is useful in small devices to save space because it reduces the number of charge pumps needed to increase low supply voltages to a desired voltage.

It is noted that the bias voltage source 500 may have a startup issue where the second booster stage 510 and the charge pump 506 load the first booster stage 508 and the bias voltage source 500 may not startup properly if the reference voltage is too small relative to Vth (making the switches have high on resistance) using traditional cross coupled inverter stages for the voltage booster stages 508 and 510. Switch control circuit embodiments described below decouple inverter switch control for the voltage booster stages 508 and 510 and use the supply voltage to improve the on-resistance Ron for a given transistor/switch size. This can allow very low reference voltages to be used. Also, the switch control of the booster stages and/or their increasing, such as quadrupling, of the reference voltage allows subsequent stages of the charge pump 506 to be standard cross coupled inverters that do not require a switch control circuit, such as a bootstrapping circuit. Decoupling the reference voltage from switch control allows further enhancements such as implementing break-before-make of the switches or other suitable switching controls to increase the efficiency of the booster stages.

As will be described below, switch control circuits, such as bootstrap switches, allow for Vgs=Vref+Vdd for NMOS and 2Vref−Vdd on voltages for PMOS. Also, separate switch control for high side and low side transistors/switches allow for true break-before-make operation to reduce shoot through current and increase efficiency.

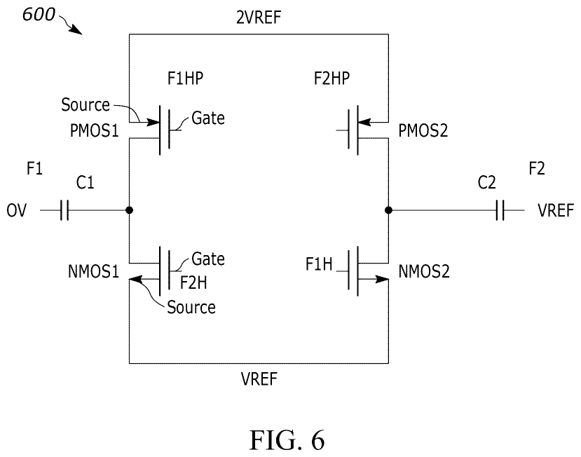

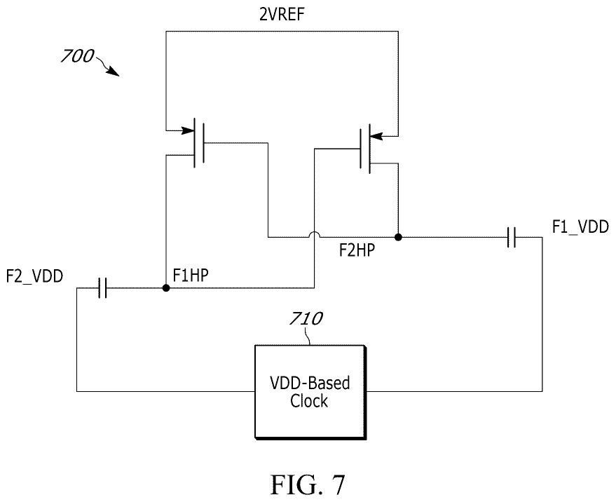

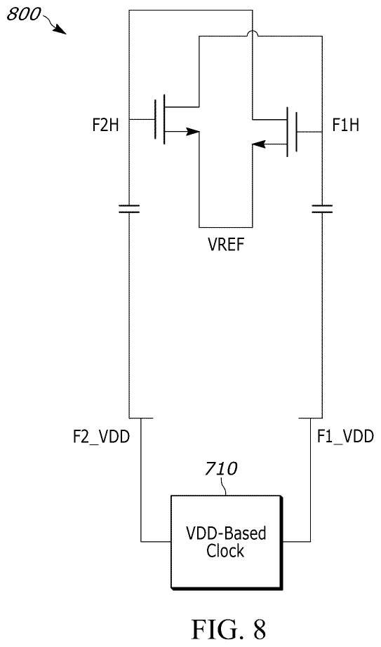

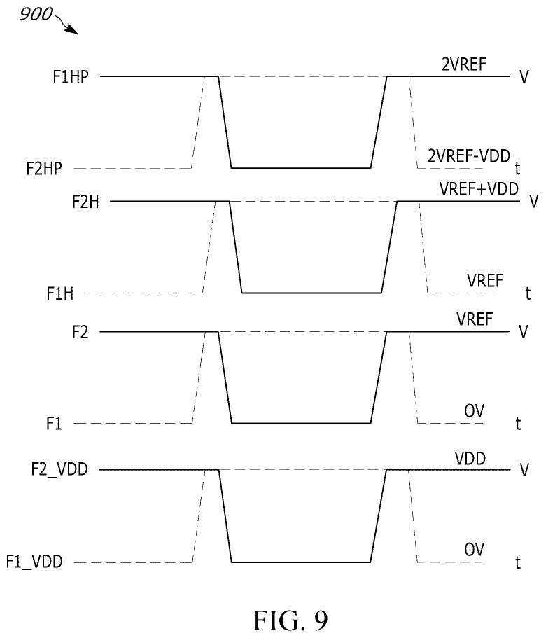

FIG. 6 is an illustration of a voltage booster stage 600, such as the first voltage booster stage 508, according to an example embodiment. FIG. 7 is an illustration of a first switch control circuit 700 according to an example embodiment. The first switch control circuit 700 can be coupled to a voltage source-based clock 710. The first switch control circuit 700 can be incorporated into the voltage booster stage 600 as described below. FIG. 8 is an illustration of a second switch control circuit 800 according to an example embodiment. The second switch control circuit 800 can be coupled to the voltage source-based clock 710. The second switch control circuit 800 can be incorporated into the voltage booster stage 600 as described below. FIG. 9 is an example diagram of signals 900 applied to the voltage booster stage 600 according to an example embodiment. The voltages 0V and VREF voltage labels represent a particular state and alternate due to the out of phase clocking signals. While labels of 0V and VREF are used for the voltages at the C1 and C2 capacitors of voltage booster stage 600, other voltages can be used, such as CLK_{REF_A} and CLK_{REF_B}, in other embodiments.

Generally, the voltage booster stage 600 includes at least two transistors, each including a gate and a source. Each transistor can be part of an inverter, such as the inverters I1 and I2 described above. The transistors/inverters would typically be cross-coupled transistors/inverters. However, the voltage booster stage 600 includes a switch control circuit, such as switch control circuit 700 and/or 800, coupled between the gates of the at least two transistors, where the switch control circuit controls at least two transistors independent of the reference voltage. The switch control circuit is considered a switch control circuit because the transistors act as switches and the switch control circuit controls the switching function of the transistors.

In an embodiment, the transistors include a first PMOS transistor having a gate, a first NMOS transistor having a gate, a second PMOS transistor having a gate, and a second NMOS transistor having a gate. The switch control circuit includes a first switch control circuit 700 coupled between the first PMOS transistor gate and the second PMOS transistor gate and includes a second switch control circuit 800 coupled between the first NMOS transistor gate and the second NMOS transistor gate. The first switch control circuit 700 can be an inverted clock booster that provides an inverted boosted clock voltage source signal to the first PMOS transistor gate and the second PMOS transistor gate. The second switch control circuit 800 can be a clock booster that provides a boosted clocked voltage source signal to the first NMOS transistor gate and the second NMOS transistor gate.

In an example embodiment, the voltage booster stage 600 includes a first voltage booster capacitor C1 and a second voltage booster capacitor C2 driven by respective complimentary clock drivers F1 and F2. The complimentary clock drivers control charging and discharging of each respective capacitor.

The switch control circuits make the gate to source voltage of the transistors independent of the reference voltage. For example, a transistor turns on when Vgs is higher than a threshold voltage. The switch control circuits turn the transistors on and off based on a gate voltage Vg that makes the gate control independent of a reference voltage applied at the source. The switch control circuit sets the Vgs independent of the reference voltage because the reference voltage at the transistor source is negated from the transistor gate voltage.

To elaborate, the switch control circuit sets Vgs based on voltage based on a source voltage different from the reference voltage. For example, for an NMOS transistor, if the source voltage is
Vs=Vref
   and the gate voltage is
Vg=Vdd+Vref,

then the gate to source voltage is

### Vgs=(Vref+Vdd)−Vref,

where Vdd turns the gate on when it is higher than the required threshold voltage Vth. Thus, the Vgs relative to the gate voltage is independent of the reference voltage Vref. In particular, the Vgs is Vdd regardless of the value of Vref.

Again, the switch control circuit adjusts a gate voltage based on the reference voltage and a voltage a different voltage than the reference voltage. For example, for an NMOS, the switch control circuit increases a gate-to-source voltage Vgs based on the reference voltage and another voltage different from the reference voltage that charges capacitors of the voltage booster stage 600. The switch control circuit decouples the control of switching the transistor on and off from the reference voltage and drives the control of switching using a voltage source having a different voltage than the reference voltage. The switch voltage control circuitry can set a gate off voltage based on the reference voltage and set a gate on voltage based on the combination of reference voltage and the source voltage. It decouples voltage booster switch control from the reference voltage and drives the switch control using a voltage source having a different voltage than the reference voltage. The switch control circuit can also control a voltage applied to a gate of a PMOS transistor separately from a voltage applied to a gate of NMOS transistor.

According to a possible embodiment, the first switch control circuit 700 can be an inverted clock booster, such as a type of voltage inverter switch controller, which can also be considered a bootstrap switch control, for the PMOS. The first switch control circuit 700 is tied to 2Vref to drop it lower by Vdd. The first switch control circuit 700 provides the F1HP and F2HP signals to the PMOS1 and PMOS2 gates.

The second switch control circuit 800 can be a clock booster, which can be a type of voltage doubler or adder switch controller, which can also be considered a bootstrap switch controller, for the NMOS. The second switch control circuit 800 adds a clocked source voltage Vdd to the reference voltage Vref. This makes Vdd the Vgs for the NMOS. The second switch circuit provides the F1H and F2H signals to the NMOS1 and NMOS2 gates.

Referring to the signals 900 of FIG. 9, F1 and F2 represent pump capacitor inputs that are clocked Vref signals provided from a clock generator to the capacitors C1 and C2. F1 and F2 provide the main clock at the reference voltage to the voltage booster stage 600. For example, overlapping clocks are fed into inverters that are running off Vref. In subsequent voltage booster stages, the F1 and F2 voltages can be higher, such as 2× Vref, which can be even higher depending on the number of stages.

F2_VDD and F1_VDD represent switch circuit control clock signals that are clocked source voltages provided to the first and second switch control circuits 700 and 800. These signals provide Vdd as reference signals, such as source signals, with different phases in phase with F1 and F2 to the first and second switch control circuits 700 and 800. They run off a VDD-based clock.

F1H and F2H represent voltages from the second switch control circuit 800 that are applied to the NMOS1 and NMOS2 gates. In a possible implementation, F1H and F2H can be considered NMOS bootstrap switch control signals. F1HP and F2HP represent voltages from the first switch control circuit 700 to the PMOS1 and PMOS2 gates. For the PMOS gates, one cycle goes up by 2Vref and down by 2Vref minus Vdd, which provides a swing from 2Vref to 2Vref Vdd. For the NMOS gates, one cycle goes up by Vref plus Vdd and down by Vref, which provides a swing from Vref+Vdd to Vref.

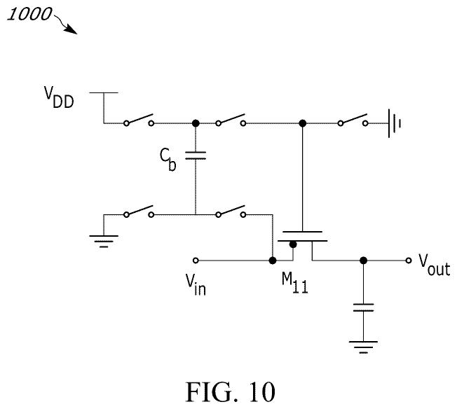

FIG. 10 is an example illustration of a bootstrapping circuit 1000 according to an example embodiment. The M₁₁ transistor functions as a switched capacitor circuit where the gate of the transistor M₁₁ is bootstrapped. In the first cycle, C_{b} is charged from VDD to ground, then C_{b} is connected from Vᵢₙ to gate of M₁₁ in the other cycle. In this case, when the switch is in the sample cycle, the Vgs of M₁₁ is V_{DD}+Vᵢₙ regardless of the value of Vᵢₙ. This gives a constant on-resistance Rₒₙ of the switch independently of Vᵢₙ. If the gate of M₁₁ is instead switched from V_{DD} to ground each cycle, the Vgs of M₁₁ would be V_{DD}-Vᵢₙ, and the Rₒₙ is determined by the relative difference in voltage from V_{DD} and V_{IN}.

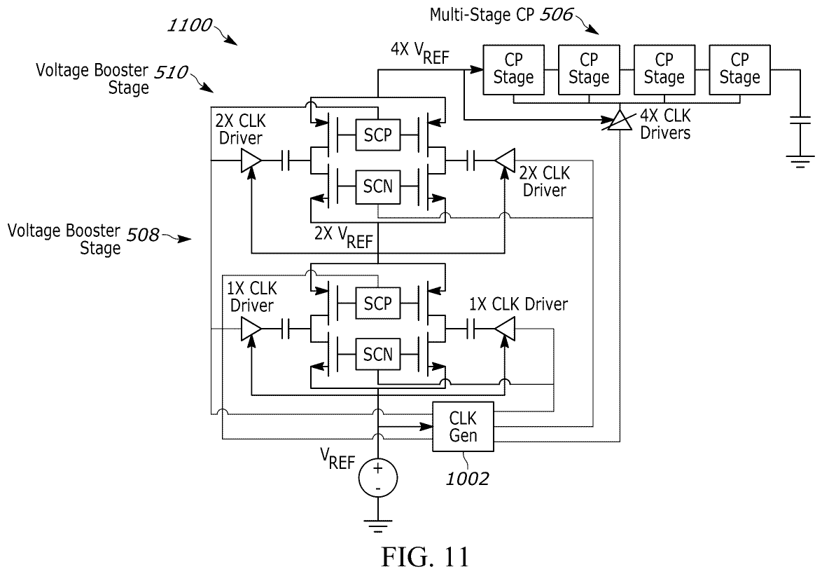

FIG. 11 is an example illustration of a bias voltage source 1100 according to an example embodiment. The bias voltage source 1100 includes elements of the bias voltage source 500, as well as switch control circuits SCP and SCN. In particular, the bias voltage source 1100 includes the multi-stage charge pump 506, the voltage booster stages 508 and 510, a clock generator 1002, and the switch control circuits SCP and SCN. The voltage booster stages 508 and 510 include PMOS switch control circuits SCP and NMOS switch control circuits SCN that perform functions of the switch control circuits 700 and 800 described above. A clock signal provided by the clock generator 1002 is driven by the 1× CLK drivers and the 2× CLK drivers into respective voltage booster stages 508 and 510. The clock signal provided to the charge pump stages of the multi-stage charge pump 506 is driven by 4× CLK drivers that receive the 4× Vref output from the voltage booster stages 508 and 510.

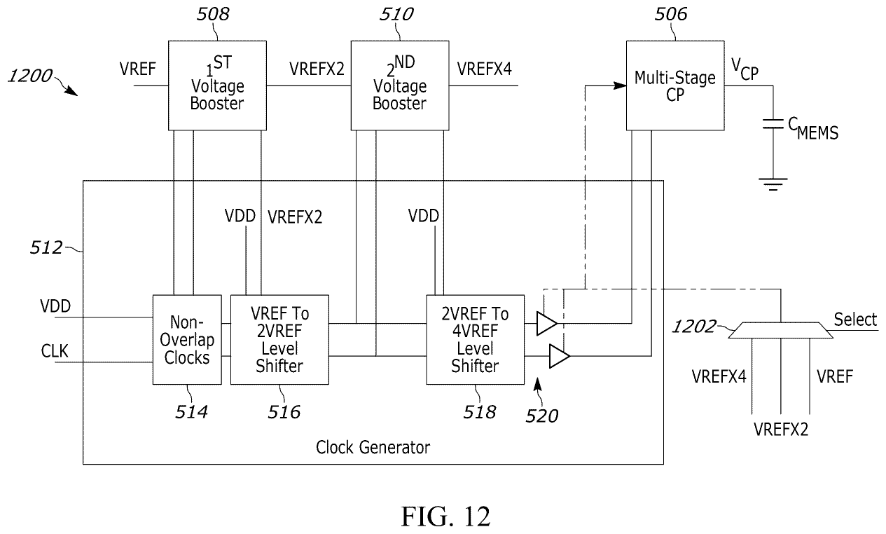

FIG. 12 is an example illustration of a bias voltage source 1200 including a multiplexer according to an example embodiment. The bias voltage source 1100 includes elements of the bias voltage sources 500 and 1100, as well as a multiplexer 1202. The multiplexer 1202 selectively enables a voltage booster output signal provided from at least one voltage booster stage of the plurality of voltage booster stages to the charge pump. The voltage booster output signal can be a multiplied reference voltage signal and/or an increased voltage clock signal. For example, the multiplexer 1202 can select Vref, Vref×2, or Vref×4 as the voltage provided to the clock drivers 520 and/or to the input of the multi-stage charge pump 506.

At least some methods of this disclosure can be implemented on a programmed processor. However, the controllers, blocks, and modules may also be implemented on a general purpose or special purpose computer, a programmed microprocessor or microcontroller and peripheral integrated circuit elements, an integrated circuit, a hardware electronic or logic circuit such as a discrete element circuit, a programmable logic device, software, firmware, or the like. In general, any device on which resides a finite state machine capable of implementing the flowcharts shown in the figures may be used to implement the functions of this disclosure.

Also, while this disclosure has been described with specific embodiments thereof, it is evident that many alternatives, modifications, and variations will be apparent to those skilled in the art. For example, various components of the embodiments may be interchanged, added, or substituted in the other embodiments. Also, all of the elements of each figure are not necessary for operation of the disclosed embodiments. For example, one of ordinary skill in the art of the disclosed embodiments would be enabled to make and use the teachings of the disclosure by simply employing the elements of the independent claims. Accordingly, embodiments of the disclosure as set forth herein are intended to be illustrative, not limiting. Various changes may be made without departing from the spirit and scope of the disclosure.

In this document, relational terms such as “first,” “second,” and the like may be used solely to distinguish one entity or action from another entity or action without necessarily requiring or implying any actual such relationship or order between such entities or actions. The phrase “at least one of,” “at least one selected from the group of,” or “at least one selected from” followed by a list is defined to mean one, some, or all, but not necessarily all of, the elements in the list. The terms “comprises,” “comprising,” “including,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a,” “an,” or the like does not, without more constraints, preclude the existence of additional identical elements in the process, method, article, or apparatus that comprises the element. Also, the term “another” is defined as at least a second or more. The terms “including,” “having,” and the like, as used herein, are defined as “comprising.” Terms of approximation, such as “approximately,” “near,” “substantially,” and/or other related terms, unless otherwise defined, are defined as a range within +/-5% of the approximated element, a range within +/−10% of the approximated element, and/or a range close enough to the approximated element to achieve an intended result. All elements of the disclosed embodiments can be modified with such terms. Furthermore, the background section is not admitted as prior art, is written as the inventor's own understanding of the context of some embodiments at the time of filing and includes the inventor's own recognition of any problems with existing technologies and/or problems experienced in the inventor's own work.

What is claimed is:

1. A sensor component comprising:
a housing;
an electrical interface disposed on an exterior of the housing;
a capacitive transducer disposed in the housing, the capacitive transducer including a first electrode and a second electrode; and
an electrical circuit disposed in the housing and electrically coupled to the capacitive transducer and the electrical interface, the electrical circuit including a bias voltage source coupled to the first electrode, the bias voltage source comprising:
a charge pump including a clock input;
a reference voltage source that provides a reference voltage;
a clock circuit that outputs a clock signal with a clock voltage; and
a voltage booster circuit coupled to the charge pump and coupled to the reference voltage source, where the voltage booster circuit receives the reference voltage and the clock signal, increases the reference voltage, and increases a voltage of the clock signal provided to the charge pump clock input based on the increased reference voltage.

2. The sensor component of claim 1, wherein the charge pump comprises a charge pump input and the voltage booster circuit provides the increased reference voltage to the charge pump input.

3. The sensor component of claim 1, wherein the voltage booster circuit comprises a plurality of voltage booster stages, where a first voltage booster stage increases a clock voltage provided to a second voltage booster stage.

4. The sensor component of claim 3, wherein the first voltage booster stage increases the reference voltage and provides the increased reference voltage to the second voltage booster stage.

5. The sensor component of claim 4, wherein
the voltage booster circuit comprises a voltage level shifter coupled to an output of the first voltage booster stage and coupled to a clock input of the second voltage booster stage, and
the voltage level shifter increases the clock voltage provided to the second voltage booster stage based on an increased reference voltage output from the first voltage booster stage.

6. The sensor component of claim 3, wherein the electrical circuit comprises a multiplexer that selectively enables a voltage booster output signal provided from at least one voltage booster stage of the plurality of voltage booster stages to the charge pump.

7. The sensor component of claim 1, wherein the voltage booster circuit comprises:
at least two transistors, each transistor including a gate and a source; and
a switch control circuit coupled between the gates of the at least two transistors, where the switch control circuit controls the at least two transistors independent of the reference voltage.

8. The sensor component of claim 7, wherein the switch control circuit controls the at least two transistors independent of the reference voltage by making a gate to source voltage of the at least two transistors independent of the reference voltage.

9. The sensor component of claim 7,
wherein the at least two transistors comprise an PMOS transistor and an NMOS transistor, and
wherein the switch control circuit controls a voltage applied to a gate of the PMOS transistor separately from a voltage applied to a gate of the NMOS transistor.

10. The sensor component of claim 7,
wherein the at least two transistors comprise:
a first PMOS transistor comprising a gate;
a first NMOS transistor comprising a gate;
a second PMOS transistor comprising a gate; and
a second NMOS transistor comprising a gate, and
wherein the switch control circuit comprises:
a first switch circuit coupled between the first PMOS transistor gate and the second PMOS transistor gate; and
a second switch circuit coupled between the first NMOS transistor gate and the second NMOS transistor gate.

11. The sensor component of claim 10,
wherein the first switch circuit comprises an inverted clock booster that provides an inverted boosted clock voltage source signal to the first PMOS transistor gate and the second PMOS transistor gate, and
wherein the second switch circuit comprises a clock booster that provides a boosted clocked voltage source signal to the first NMOS transistor gate and the second NMOS transistor gate.

12. The sensor component of claim 1, wherein the voltage booster circuit comprises a first voltage booster capacitor and a second voltage booster capacitor driven by respective complimentary clock drivers, where the complimentary clock drivers control charging and discharging of each respective capacitor.

13. The sensor component of claim 1,
wherein the charge pump comprises an output, and
wherein the bias voltage source comprises a low pass filter coupled between the charge pump output and the capacitive transducer.

14. The sensor component of claim 1, wherein the electrical circuit comprises a non-inverting amplifier including an input coupled to the capacitive transducer, where the non-inverting amplifier has an input impedance greater than 1 TΩ.

15. A sensor component comprising:
a housing including a sound port;
an electrical interface disposed on an exterior of the housing;
a microelectromechanical systems (MEMS) transducer disposed over the sound port, the MEMS transducer separating the housing into a front volume acoustically coupled to the sound port and a back volume on an opposite side of the MEMS transducer from the sound port; and
an electrical circuit disposed in the housing and electrically coupled to the MEMS transducer and to the electrical interface, the electrical circuit including a bias voltage source coupled to a first electrode of the MEMS transducer, the bias voltage source comprising:
a charge pump comprising a plurality of charge pump stages, each charge pump stage comprising a charge pump stage clock input;
a reference voltage source that provides a reference voltage;
a clock circuit that outputs a clock signal with a clock voltage; and
a voltage booster circuit coupled to the charge pump and coupled to the reference voltage source, where the voltage booster circuit receives the clock signal, and increases a voltage of the clock signal provided to each charge pump stage clock input based on the reference voltage.

16. The sensor component of claim 15,
wherein the voltage booster circuit comprises a plurality of voltage booster stages, where a first voltage booster stage increases a clock voltage provided to a second voltage booster stage, and
wherein the first voltage booster stage increases the reference voltage and provides the increased reference voltage to the second voltage booster stage.

17. The sensor component of claim 15, wherein the voltage booster circuit comprises:
at least two transistors, each transistor including a gate and a source; and
a switch control circuit coupled between the gates of the at least two transistors, where the switch control circuit controls the at least two transistors independent of the reference voltage.

18. The sensor component of claim 17,
wherein the at least two transistors comprise:
a first PMOS transistor comprising a gate;
a first NMOS transistor comprising a gate coupled to the first PMOS transistor gate;
a second PMOS transistor comprising a gate; and
a second NMOS transistor comprising a gate coupled to the second PMOS transistor gate, and
wherein the switch control circuit comprises:
a first switch circuit coupled between the first PMOS transistor gate and the second PMOS transistor gate; and
a second switch circuit coupled between the first NMOS transistor gate and the second NMOS transistor gate.

19. A sensor component comprising:
a housing;
an electrical interface disposed on an exterior of the housing;
a capacitive transducer disposed in the housing, the capacitive transducer including a first electrode and a second electrode; and
an electrical circuit disposed in the housing and electrically coupled to the capacitive transducer and the electrical interface, the electrical circuit including a bias voltage source coupled to the first electrode, the bias voltage source comprising:
a charge pump including a clock input;
a reference voltage source that provides a reference voltage;
a clock circuit that outputs a clock signal with a clock voltage; and
a voltage booster circuit coupled to the charge pump and coupled to the reference voltage source, where the voltage booster circuit receives the reference voltage and the clock signal, increases the reference voltage, and increases a voltage of the clock signal provided to the charge pump clock input based on the increased reference voltage, where the voltage booster circuit includes:
at least two transistors, each transistor including a gate and a source; and
a switch control circuit coupled between the gates of the at least two transistors, where the switch control circuit controls the at least two transistors independent of the reference voltage.

20. The sensor component of claim 19, wherein the switch control circuit controls the at least two transistors independent of the reference voltage by making a gate to source voltage of the at least two transistors independent of the reference voltage.
